(19) United States
(12) Patent Application Publication
(10) Pub. No.: US 2009/0192738 A1
(43) Pub. Date: Jul. 30, 2009

(54) CALIBRATION TECHNIQUE FOR POWER AMPLIFIERS

(75) Inventor: Markus Nentwig, Helsinki (FI)

Correspondence Address: PERMAN & GREEN, 425 POST ROAD, FAIRFIELD, CT, 06824, US

(73) Assignee: NOKIA CORPORATION, Espoo (FI)

(21) Appl. No.: 12/358,363

(22) Filed: Jan. 23, 2009

(30) Foreign Application Priority Data
Jan. 25, 2008 (GB) 0801413.6

(51) Int. Cl. G06F 19/00; G01R 13/00

(52) U.S. Cl. 702/66

(57) ABSTRACT

A method of calibrating an amplifier includes receiving input and output samples, wherein the input and output samples are time-aligned, assigning at least one of the input and output samples to one of a plurality of categories based on the input sample, and estimating at least one characteristic of the amplifier based on the contents of at least one of said plurality of categories.

### FIELD OF THE INVENTION

The present invention relates to a method and apparatus and, in particular but not exclusively, to a method for calibrating power amplifiers for use in a device in a telecommunications system.

### BACKGROUND

Amplification is required in various communication applications. For example, radio frequency signals transmitted between signaling points in a radio communications system may need to be amplified during some stage of the transmission and/or reception. The amplification of the signals is required since the amplitude of a signal tends to be attenuated during the transmission of the signal between the signaling points, thereby decreasing the quality of the transmission. Power amplifiers are commonly used in mobile terminals to amplify a signal to be transmitted and provide the radio frequency energy that is ultimately radiated from the antenna.

Early radio standards (for example GSM) use constant envelope signals, meaning the average power on a symbol time scale is almost constant. Therefore, a power amplifier can be used that is optimized to operate at that constant average power. However, more advanced radio systems (e.g. WCDMA and its LTE extension, WLAN, etc) use signals with a variable envelope. This leads to higher spectral efficiency, but requires the use of a linear power amplifier to amplify the signals.

Due to the underlying technology used to produce power amplifiers for use in radio frequency applications (e.g. Gallium Arsenide (GaAs)), power amplifiers are inherently nonlinear devices. Any amplifier introduces AM-PM (amplitude modulation—phase modulation) distortion, where amplitude variations in the input signal cause undesirable phase variations in the output signal, and AM-AM distortion, which causes variations in amplifier gain depending on the input signal amplitude. The non-linearity in the power amplifier devices will introduce errors into the amplified signal, and may limit the efficiency of the power amplifier. Furthermore, any distortions in the amplified signal, as will be caused by the non-linearity of the power amplifier, may lead to frequency components being present in the amplified signal that are outside of the desired transmission band. Such unwanted out-of-band emissions serve no useful purpose and the energy contained in these signals reduces the operating efficiency of the transmitter. Furthermore, the unwanted frequency components manifest as noise in the relevant frequencies, and may cause interference for communications links using the effected frequencies. If these unwanted emissions fall within the frequencies allocated to the operator of the communications network, they may reduce the efficiency with which the radio spectrum may be used. Spurious radio emissions outside of an operator's allocated frequencies may be strictly regulated, so as to ensure that operators do not interfere with each others' spectrum allocation.

A number of techniques have been proposed to linearise the output of amplifiers. One such technique is predistortion. In predistortion the input signal is deliberately distorted prior to being inputted to the power amplifier in a manner that is contrary to that distortion that the signal will experience in the amplifier itself, resulting in a ‘cleaner’ signal.

However, in order to correctly predistort the input signal, the distortion due to the amplifier must be known. Accurate determination of the distortion characteristics of the amplifier allows more effective linearization of the amplifier using predistortion.

Accurate correction of non-linearity in the amplifier may be necessary to meet requirements on power emissions in adjacent frequencies not allocated to the radio transmitter for certain radio standards, and therefore the power amplifier characteristics need to be known to meet the requirements on emissions in adjacent frequencies. Therefore, power amplifiers may be measured to characterize the non-linearity of the amplifier during production of transmitting terminals, and the characterizing information may be written to the device's permanent memory to allow correct predistortion of the input signal to linearize the output of the amplifier.

Due to parameter variations between batches and even individual samples within a batch it is sometimes necessary to characterize the non-linearity of each individual power amplifier module separately during production. This allows the required predistortion to correct for the non-linearity to be accurately determined for each sample. However, production testing may be a slow and laborious process, and presents a production bottleneck and may significantly increase the costs associated with production. These problems may be particularly acute in the case of high volume products.

In conventional production testing, the power amplifier is driven with a continuous-wave signal (sine wave) at different power levels. The relationship between the input and output signals is observed and the variations in gain and phase are recorded. This results in so-called AM-AM and AM-PM curves. This data represents the amplitude (AM-AM) and phase (AM-PM) error for signals amplified by the power amplifier for different power levels, compared to a theoretical ideal amplifier.

A continuous wave test signal gives a single point on the AM-AM and AM-PM error curves for each input power. The use of a continuous wave test signal allows the steady state condition of the circuit to be determined, but it is very different from an actual modulated signal, and therefore may not truly represent normal operation of the amplifier.

In fact, for any power amplifier, there is not a single “AM-AM” or “AM-PM” curve. Instead, for each instantaneous input power there is a probability distribution of amplitude and phase error. When measuring with a sine wave, the result is only a single point on that probability distribution, and the determined value may not necessarily provide an average that is representative for the distribution observed with a modulated signal. The characteristics of a sine wave test signal are very different from an actual modulated signal, and this may lead to differences between the recorded error value at a particular instantaneous input power, and the average error value that would be experienced by applying a more realistic input signal. This leads to a systematic error being present in the predistortion data determined using this prior art technique.

Furthermore, measurement of the error values for all instantaneous input signal powers requires a power sweep, and is therefore slow. It may also be inaccurate because of the memory effect exhibited by the amplifier nonlinearity, whereby the error in an amplified signal may depend on the condition of the power amplifier due to the previous signals. Current implementations may use a simple AM-AM/AM-PM model that does not take into account the memory effect between samples.

A further issue exists that the characteristics of power amplifiers may change after production testing due to various environmental factors. In particular, it is known that the non-linearity of a power amplifier may vary with, for example, temperature, and with aging of the device. Therefore, calibration of the device during production may no longer accurately represent the characteristics of the power amplifier after a period of use.

It may therefore be beneficial for future radio systems to include mechanisms to perform PA calibration during device operation. This might lead to better RF performance, and other advantages such as longer battery life.

WO2007/44957 relates to a digital predistortion method for linearizing a transmit amplifier. The method relies on the presence of a standard ramp signal transmitted during the PA power up or down ramp. Such a signal is common in certain standards such as the EDGE burst power ramp, however this signal is not universal, and the method is therefore not generally applicable. In order to precisely calibrate the required predistortion, WO 2007/44957 uses a staircase ramp signal to be applied to the power amplifier, with time allowed for the output to settle before measurements are taken after each stage. Therefore, this system operates in a similar way to the conventional production testing methods described above.

‘Power Amplifier Linearization using Cubic Spline Interpolation’; Lohtia et al, describes a simple predistortion scheme in which the demodulated amplifier output is compared with the baseband input signal in order to estimate the amplifier's AM-AM and AM-PM characteristics, using cubic spline interpolation.

‘Linear Amplification Techniques for Digital Mobile Communications’; Nagata, Y, describes a prior art method of estimating amplifier characteristics in order to predistort a signal applied to the amplifier using a realistic test signal. The algorithm is iterative and requires a very large sample bandwidth, at least twice the distortion bandwidth which is itself at least three channels wide. This means that this method is not suitable for applications in which processing power may be limited.

It is an aim of some embodiments of the present invention to address, or at least mitigate, some of these problems.

### SUMMARY

According to a first aspect of the present invention, there is provided a method of characterizing an amplifier, the method comprising receiving input and output samples, wherein said input and output samples are time-aligned; assigning at least one of said input and output samples to one of a plurality of categories based on said input sample; and estimating at least one characteristic of the amplifier based on the contents of at least one of said plurality of categories. Preferably, the method further comprises determining a phase difference between said input sample and said output sample. Determining said phase difference may comprise modifying the phase of one of said input and output samples to represent the phase difference. Modifying the phase of one of said input and output samples may comprise rotating a phase of the output sample backwards by a phase of the input sample. Rotating the phase of the output sample may be achieved by calculating a complex phasor having an opposite phase to said input sample and multiplying said output sample with said complex phasor.

Preferably, assigning at least one of said input and output samples to one of a plurality of categories may further comprise determining a bin index based on the magnitude of the input sample. The output sample may be stored in a bin of a first bin array having a bin index equal to the determined bin index. The magnitude of the input sample may be stored in a bin of a second bin array, said bin having an index equal to said determined index. Optionally, storing said output sample in a bin may comprise adding the output sample to the contents of the bin of the first bin array, and storing the magnitude of said input sample in a bin may comprise adding the magnitude of the input sample to the contents of the bin of said second bin array.

Preferably, estimating at least one characteristic of the amplifier comprises dividing the contents of each bin in said first bin array by the contents of the corresponding bin in said second bin array. Estimating at least one characteristic of the amplifier may comprise estimating a gain error for said amplifier based on the magnitude of a result of said division and estimating at least one characteristic of the amplifier may comprise estimating a phase error for said amplifier based on a phase of a result of said division.

Optionally, said storing said magnitude of said input sample further comprises applying a first function to the magnitude of said input sample prior to storing. Said first function may comprise a square function. Said storing said output sample may further comprise applying a second function to the output sample prior to storing. Said second function may comprise multiplying said output sample by the magnitude of the output sample. Estimating at least one characteristic of the amplifier may further comprise applying a third function to the contents of each bin in said second bin array. Said third function may comprise a square root function. Estimating at least one characteristic of the amplifier may further comprise applying a fourth function to the contents of each bin in said first bin array. Said fourth function may be defined by the equation:

y=\sqrt{abs(aᵢ)}*l^{j*arg(a}^{ᵢ}⁾

wherein aᵢ defines the contents of the bin in said first bin array with bin index i, and j is equal to the square root of minus one.

According to a second aspect of the present invention, there is provided an apparatus comprising a receiving unit configured to receive time-aligned input and output samples, an assigning unit configured to assign at least one of said input and output samples to one of a plurality of categories based on said input sample, and an estimating unit configured to estimate at least one characteristic of the amplifier based on the contents of at least one of said plurality of categories.

Preferably, the apparatus may further comprise a phase determining unit configured to determine a phase difference between said input sample and said output sample. Said phase determining unit is may be configured to modify the phase of one of said input and output samples to represent said phase difference. Said assigning unit may be further configured to determine a bin index based on a magnitude of said input sample. The assigning unit may further comprise a first bin array comprising a plurality of bins, and a storing unit configured to store said output sample in a bin of said first bin array, said bin having an index equal to the determined bin index. The assigning unit may further comprise a second bin array comprising a plurality of bins, and wherein said storing unit is further configured to store said magnitude of said input sample in a bin in said second bin array, said bin having an index equal to the determined bin index. Said storing unit may be further configured to store said output sample in said bin in said first bin array by adding the output sample to the contents of the array. Said storing unit may be further configured to store said magnitude of said input sample in said bin in said second bin array by adding the magnitude of said input sample to the contents of the array.

According to a third aspect of the present invention, there is provided an apparatus comprising receiving means for receiving time-aligned input and output samples, assigning means for assigning at least one of said input and output samples to one of a plurality of categories based on said input sample, and estimating means for estimating at least one characteristic of the amplifier based on the contents of at least one of said plurality of categories.

According to a fourth aspect of the present invention, there is provided computer program code means adapted to perform any of the method steps of the invention when the program is run on a processor.

### BRIEF DESCRIPTION OF THE DRAWINGS

Embodiments of the present invention will now be described by way of example only with reference to the accompanying Figures, in which:

FIG. 1 illustrates a method of characterizing a power amplifier according to one embodiment of the present invention;

FIG. 2 illustrates an apparatus suitable for collecting input/output samples during production testing in accordance with a further embodiment of the present invention.

FIG. 3 illustrates an apparatus suitable for collecting input/output samples in a mobile device in accordance with a further embodiment of the present invention.

FIG. 4 illustrates an apparatus suitable for collecting input/output samples for a signal received via a communications link in accordance with a further embodiment of the present invention.

FIG. 5 shows example AM-AM characteristics determined using an embodiment of the present invention compared with using a continuous wave signal;

FIG. 6 shows example AM-PM characteristics determined using an embodiment of the present invention compared with using a continuous wave signal;

### DESCRIPTION OF PREFERRED EMBODIMENTS

Embodiments of the present invention are described herein by way of particular examples and specifically with reference to preferred embodiments. It will be understood by one skilled in the art that the invention is not limited to the details of the specific embodiments given herein.

In some embodiments of the present invention, a modulated signal is used to characterize the power amplifier, or device under test (DUT) 2. Such a test signal should have similar statistical properties as those expected during operation of the power amplifier, and may for example be an actual signal of the relevant radio standard. The test signal may be generated by the transmitter hardware in the device containing the amplifier being characterized. In one embodiment, pseudorandom data is used to generate the test signal.

This leads to baseband-equivalent IQ (in-phase—quadrature) data streams to be present as modulation on a radio frequency carrier on the input and output of the power amplifier 2 to be characterized.

The test signal provides many different input magnitudes and results in associated amplitude and phase errors in the power amplifier output. The amplitude and phase errors are observed and treated as probability density versus instantaneous input power.

Since the statistics of the realistic test signal are the same as those of the expected signals during operation of the power amplifier, the different measurements accurately reflect the probability distribution of error vectors over input power. However, for the AM-AM/AM-PM model used in known digital predistorters, only a single point for each input power is required. These points may be found by averaging all observed errors at each input power, to find an average of the probability distribution of error vectors at that power.

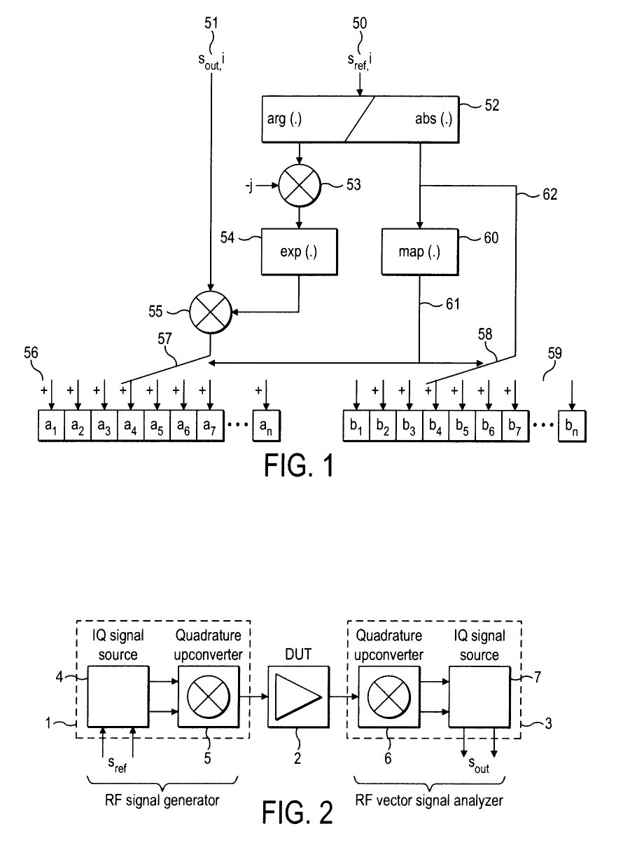

FIG. 1 illustrates a method according to one embodiment of the present invention that may be used to determine the characteristics of a power amplifier. The method uses two sample streams, S_{ref} and sₒᵤₜ representing the data stream that is applied to the power amplifier and the data stream including distortion products due to the power amplifier respectively. Preferably, the sample streams are time aligned, that is, any processing delay in the output stream has been compensated, so that crosscorrelation between sample streams, s_{ref} and sₒᵤₜ, is maximized. One possible method of aligning the sample streams is discussed below.

The method processes one input sample 50, S_{ref, i}, and one output sample 51, s_{out, i}, at a time. The undistorted input sample 50 is split into amplitude and phase components in splitting function 52, i.e. abs(s_{ref, i}) and arg(s_{ref, i}) respectively. A complex phasor is constructed by multiplying the phase of the input sample 50 by —j in multiplier 53, and then calculating l^{—jarg(s}^{_{ref,i}}⁾ in exponent function 54, the phasor having unity amplitude and a phase opposite that of s_{ref, i}. Output sample s_{out, i} is then multiplied by the complex phasor in multiplier 55, this has the effect of phase rotating the output sample s_{out, i} such that the resultant phase equals the phase error distortion introduced to that sample by the power amplifier.

First and second bin arrays, 56 and 59, may be provided, each array containing n bins. The bins in each array may be identified using a bin index 61, wherein the bin index equals 1 to n, such that for each index i, one bin in each array is identified, forming a pair of bins. According to one non-limiting example, n may equal 64 bins, however other values of n may be chosen depending upon the required resolution of the characterization data. Bins may be initialised with a value of zero before any samples have been processed.

A mapping function 60 determines a bin index 61 that identifies a pair of bins. The bin index is determined based on the amplitude of input sample s_{ref, i}, i.e. abs(s_{ref, i}). In one exemplary embodiment of the invention, the bin index 61 may be proportional to the logarithm of the magnitude.

A dispatcher (array offset) 57 assigns the result from complex multiplication 55 to a complex-valued bin (a₁:aₙ) in array 56, according to index 61, in which the sample value may be stored. According to an exemplary embodiment, storing the sample in the complex valued bin may comprise accumulating the sample with the current value in said bin using complex addition. Similarly, dispatcher (array offset) 58 assigns the absolute value 62 of the undistorted input sample S_{ref, i} to be stored in a bin (b₁:bₙ) in array 59, according to index 61. According to an exemplary embodiment of the invention, storing the absolute value 62 may comprise accumulating it with the previous value of the bin using real-valued addition.

The above described process may be repeated for a sufficient number of samples, for example according to one exemplary embodiment 192000 samples at a rate of 38.4 Msps may be used, leading to a total measurement time of 5 ms, however more or less samples may be used as required. The samples do not need to be consecutive, and the total measurement time may be split into a number of separate shorter measurements.

Once a sufficient number of samples has been processed, the distortion data may be calculated from the values stored in bin arrays 56 and 59, having equal index i. For array 59, the square of each bin value bi corresponds to an input power level. The absolute value of bᵢ/aᵢ corresponds to the gain error at said power level. The phase of bᵢ/aᵢ corresponds to the phase error at said power level.

In a further embodiment of the present invention, only one bin array may be provided, corresponding to array 56. The average input signal magnitude corresponding to the contents of each bin may then be determined from the bin index 61 and the mapping function 60. If array 59 is not used, one may use knowledge of the transmitted signal instead (as for the same signal, the resulting contents of bin array 59 will remain the same). Alternatively, one could use an array of counters in place of array 59.

According to one embodiment of the present invention, the gain and phase error at power levels falling between those provided by array 59 are calculated using suitable interpolation between known values. Examples of suitable interpolation methods include nearest neighbor, linear or higher order interpolation.

According to further embodiments of the present invention, rather than assigning samples to bins, sample pairs may be stored as pairs of values in an array and ordered according to the magnitude of the input sample. Characterization data may then be calculated based on the ordered array. In one embodiment of the present invention, values assigned to bins may include a weighting factor based on the distance between the sample value and a value representing the centre of the bin.

According to one embodiment of the invention, a first function may be applied to each sample prior to storing the sample in the selected bin. In one non-limiting exemplary embodiment of the present invention, the magnitude of the input sample 62 may be multiplied by itself and then accumulated in the selected bin in bin array 59. In a further non-limiting exemplary embodiment of the present invention, each output sample may be multiplied by its magnitude before being accumulated in the selected bin in bin array 56.

According to a further embodiment of the present invention a second function may be applied to the contents of each bin prior to use of the values stored therein in calculating the distortion characteristics. In one embodiment of the present invention, a square root may be taken of the value relating to the input sample values held in each bin of bin array 59. In a further non-limiting exemplary embodiment of the present invention a value to be used in determining the distortion characteristics may be calculated from the contents of each bin in bin array 56, wherein the value is defined as:

y=\sqrt{abs(aᵢ)}*l^{j*arg(a}^{ᵢ}⁾

wherein aᵢ defines the contents of the bin in bin array 56 with bin index i, and j is equal to the square root of minus one.

In some embodiments of the present invention, the first and second functions may be used at the same time for values stored either or both bin arrays 56 and 59.

The described use of functions may have further advantages; in particular it allows the basis for which the averaging of the samples is performed to be changed. For instance, averaging may be performed with respect to signal power represented by each sample rather than the magnitude of the sample. However, the use of the described functions may significantly increase the processing requirements for some embodiments of the present invention.

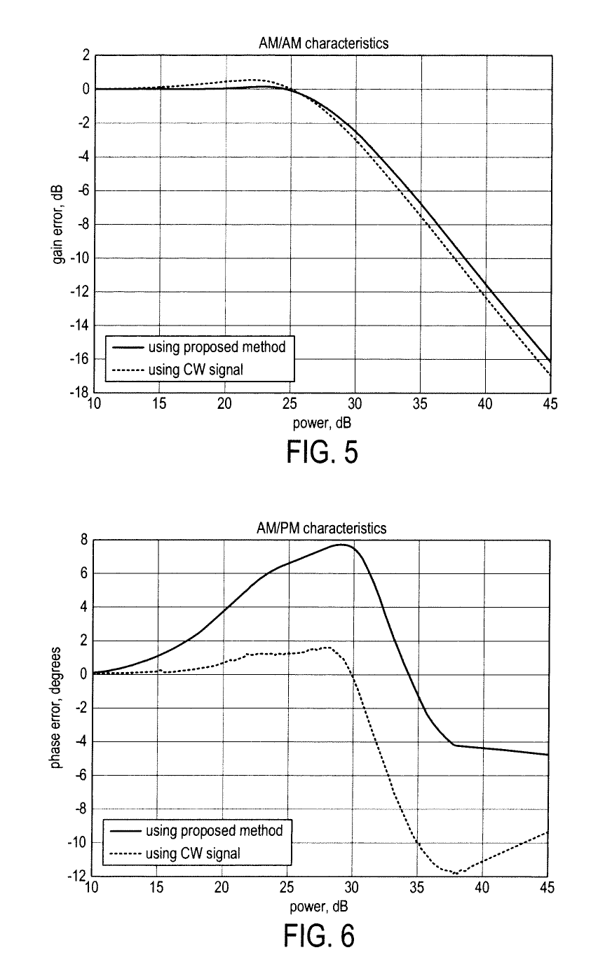

FIGS. 5 and 6 show the differences between characterization data obtained using a method according to one embodiment of the invention, and that obtained using the prior art technique of using a continuous wave test signal.

A circuit suitable for collecting the input and output sample data required to characterize the power amplifier 2, according to one exemplary embodiment of the present invention, is shown in FIG. 2. An IQ data stream representing a modulated signal, S_{ref}, is uploaded to an IQ signal source 4 in an RF signal generator 1 with arbitrary waveform generation capabilities. The signal is upconverted to a radio frequency in quadrature upconverter 5, and then applied to an input of the device under test 2. The maximum output power level at the output of power amplifier 2 should correspond to the highest output power at that node required to meet the maximum power requirement of the relevant radio standard. The signal at the output of the power amplifier 2 is then applied to an input of a RF vector signal analyzer 3. The signal is downconverted in quadrature downconverter 6 and sampled and stored in IQ data storage 7 in the RF vector signal analyzer 3 resulting in a stream of output samples sₒᵤₜ.

The sample streams are time aligned such that each sample of sₒᵤₜ is paired with the sample of s_{ref} that was applied to the power amplifier 2 to produce that output value. Alignment of the sample streams may be achieved using standard correlation techniques.

One possible technique used in relation to one embodiment of the present invention to align the sample streams is FFT (Fast Fourier Transform) correlation. This allows a crosscorrelation coefficient between the transmitted and received signal to be calculated in order to find the optimum signal alignment, when the absolute timing between the transmitted and received signals is unknown.

Frequency domain representations A=fft(sₒᵤₜ) and B=fft(sᵢₙ) are calculated, with fft( ) being the Fast Fourier Transform. The complex conjugate of B is multiplied with A on an element-by-element basis. An inverse FFT function is then performed on the product, and the result of this inverse FFT is a vector of complex numbers giving the magnitude and phase. The index of the value with peak amplitude gives an optimum delay that may be used to align the sample streams.

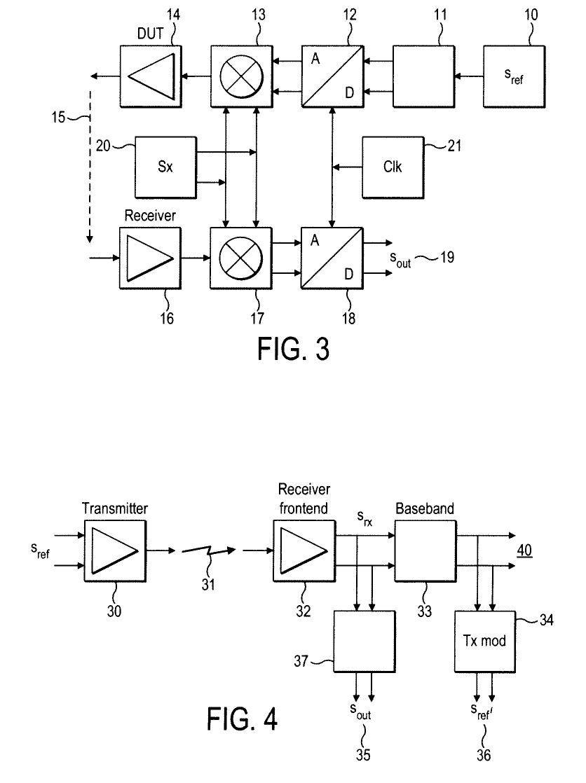

FIG. 3 shows a circuit suitable for implementing one embodiment of the invention for use in a mobile station. A test signal, s_{ref,u}, may be generated using a simple pseudorandom sequence generator 10, implemented in the mobile device. The generator may be reset periodically, generating a cyclic bit stream. The bit stream is applied to an input of a baseband processor 11, in which it is converted to a digital in-phase and quadrature signal of the desired modulation. The in-phase and quadrature portions of the signal are output from the baseband processor 11, and applied to a dual digital to analogue converter 12. Converter 12 also receives a clock signal supplied by clock circuit 21. The resulting analogue signal output by converter 12 is applied to quadrature mixer 13, which also receives local oscillator signals from common synthesizer 20. The analogue signals are upconverted to radio frequency in the quadrature mixer 13, and the upconverted signal is provided on an output of the quadrature mixer 13. The upconverted signal is then applied to an input of the device under test, or power amplifier 14.

The transmitter chain described above comprises the standard transmit functionality of a mobile station, with the addition of a pseudorandom sequence generator 10.

A coupling path 15 is provided between the output of the power amplifier 14, and the input of a receiver (which may comprise a low-noise amplifier) 16. This coupling path allows a portion of the transmitted signal to be looped back into the receiver. It may not be necessary to provide any additional hardware to realize coupling path 15, as parasitic coupling mechanisms, which are undesirable in normal operation, may provide sufficient signal strength at the input of the mobile device's receiver 16. Alternatively, a switch may be used to couple a fraction of the transmitted radio frequency signal at the output of power amplifier 14 to the input, an intermediate node or the output of receiver 16.

In the receiver 16, the signal is amplified or attenuated (depending upon the magnitude of the signal provided by coupling path 15) by a low noise amplifier 16, and then downconverted to a baseband signal using a quadrature downconverter 17. The downconverter 17 receives local oscillator signals, in common with upconverter 13, from common synthesizer 20. The baseband signal is then output from the downconverter 17 and applied to a dual analogue to digital converter 18. Analogue to digital converter 18 receives a clock signal, in common with digital to analogue converter 12, supplied by clock circuit 21. The output of the analogue to digital converter 18 is the sample stream s_{out,u}. Sample streams s_{ref,u} and s_{out,u} may be time aligned, resulting in sample streams s_{ref} and sₒᵤₜ which may be used to characterize the power amplifier. As a common synthesizer 20 is used to provide the local oscillator signals for quadrature upconverter 13 and quadrature downconverter 17, and similarly a common clock source 21 drives the converters 11 and 18, there is no relative frequency drift. Also, most of the phase noise appears at lower frequencies and cancels out. Since all relevant errors regarding frequency drift are eliminated, the measurement may be run in the background in short bursts over a long period of time. Loopback testing may also be performed during normal device operation, unnoticed by the user.

One possible scenario is that a radio standard may support ‘dumb’ loopback calibration. In this case, the base station permits the device during periods of low network load to occupy parts of the operator's spectrum for one radio frame, without requiring the base station to listen, thus allowing the mobile station to generate some characterization data.

In other embodiments, network support may not be available. In this case, it may be possible to tune the transmitter during idle periods to a frequency where the duplex filter has good isolation. Therefore, most of the energy provided at the output of the device under test will be prevented from leaving the device. The length of the test signal is then calculated to ensure that the transmitted energy falls below the level allowed by the radio standard for spurious emissions.

Some embodiments of the invention provide a characterization technique for power amplifiers that is suitable for production testing. Advantages of some embodiments of the invention over prior art production testing techniques include: the use of the mobile terminal for signal generation avoiding the need for a signal generator; fast (may take as little as a few milliseconds) calibration of the amplifier which avoids problems due to temperature changes during measurement; and it may give better results than continuous wave testing, since the test signal exhibits realistic statistics of the signal that will be applied during normal operation, avoiding the systematic error caused by the use of continuous wave test signals.

Furthermore, some embodiments of the present invention are able to characterize operation of the amplifier during normal transmission, to allow ongoing calibration of the power amplifier during use, and may therefore allow for aging effects and/or environmental effects in the power amplifier. The calibration may be performed either in a mobile terminal, or in a base station receiving transmissions from the mobile terminal. Once the required samples of the input and output signals have been obtained, the performance of the required operations is not time critical, and may be scheduled to use idle processor time on a general purpose CPU.

A further embodiment of the present invention will now be described with reference to FIG. 4 in which signals received via a radio link may be used to determine characteristics of a transmitter. The proposed characterization method is very insensitive towards added noise, as caused by the radio channel. As the noise will be uncorrelated with the signal, this noise will average out with a sufficient number of samples.

Taking the example of a least squares algorithm, the robustness to noise can be explained as follows: There are, for example, a thousand times more samples than model parameters. Each model parameter gives one dimension (or two, if it is a complex parameter) in the signal space spanned by the distortion products. Now the number of dimensions in the original signal scales with the number of samples, for example is may be a thousand times as high. Consequently, only 0.001% (−30 dB) of noise power falls into dimensions that also exist in the signal space of distortion products, and have an impact on the result. For a receiver signal to noise ratio of only 10 dB and an error vector magnitude of −15 dBc, the inband distortion products are 5 dB below the noise floor. According to the above argumentation, the effective noise is 30 dB lower, leaving an effective SNR of 25 dB for the algorithm, which is sufficient. Therefore, it is possible to calibrate the power amplifier even through a radio link.

FIG. 4 shows an embodiment in which a transmitter 30 may be characterized using the signals received at a receiver. The receiver may, for example, comprise a base station or a mobile station in a communications network. Input signals s_{ref} are applied to the input of the device under test, transmitter 30. The resultant output signals are transmitted as signals 31, which are received at a receiver.

The device under test 30, for example a mobile transmitter, transmits during ordinary operation a signal s_{ref} via a radio link 31. At the other end of the radio link, the signal is downconverted and digitized by an analogue frontend 32 including a dual analogue to digital converter (not shown). The resulting digitized baseband signal Sᵣₓ is demodulated and decoded by the baseband processor 33, including standard receiver functionality to compensate for imperfections (for example carrier frequency estimation and tracking, channel estimation and equalization) resulting in digital data 40.

The same processing to remove radio frequency imperfections is applied to the signal sᵣₓ by a processing block 37, providing signal sₒᵤₜ 35. Assuming error-free reception (which may be confirmed, for example, using parity bits, etc.) a transmitter modulation algorithm 34 identical to the one found in transmitter 30 as required by the radio standard, reconstructs s_{ref}' from the received data 40, and time-aligns sₒᵤₜ35 and s_{ref}' 36. This processing step is not time critical, and may be performed in software whenever idle CPU time is available.

The received signal 35 and the reconstructed ‘ideal’ signal 36 may then be used in conjunction with the above disclosed method to extract the required power amplifier characteristics. This may involve implementing the method to characterize the power amplifier within the receiver 32, and thereafter providing characterization data to the device under test 30 via the network. In an alternative embodiment, a model of the power amplifier may be extracted from the data and transmitted to the device under test 30.

Other options for characterizing the power amplifier using data received at the receiver may include, providing the raw data, model, or correction data to a centralized server. Data may be collected at the server over an extended period of time. Once a suitable amount of data has been collected, feedback may be provided to the device under test using a model, or correction data via the same or a different base station. Such characterization data updates may be provided as part of an automated firmware upgrade.

Compared to current production testing techniques, embodiments of the present invention are extremely fast, approximately 5 ms measurement time will be enough, and more accurate. Furthermore, the described method is able to reuse the built-in transmitter functionality of a mobile device for fast signal generation.

In a mobile device, or if computing resources are constrained, the disclosed method may be implemented with arbitrary low power in a loopback configuration. A certain number of samples must be captured and stored, but it is not necessary to capture them during the same burst. In the extreme case, a single sample may be taken at a time, at irregular intervals.

When implemented on a mobile device or base station, several possible applications of the described characterization technique have been disclosed. Embodiments of the present invention may be used to calibrate amplifiers located in mobile devices and/or base station transmitters.

Better calibration of power amplifiers using some embodiments of the present invention may lead to fewer out-of-band emissions, improving network capacity, and may also lead to higher power efficiency of the transmitting device, allowing a longer battery life for a mobile terminal. In general, the various embodiments of the invention may be implemented in hardware or special purpose circuits, software, logic or any combination thereof. For example, some aspects may be implemented in hardware, while other aspects may be implemented in firmware or software which may be executed by a controller, microprocessor or other computing device, although the invention is not limited thereto. While various aspects of the invention may be illustrated and described as block diagrams, flow charts, or using some other pictorial representation, it is well understood that these blocks, apparatus, systems, techniques or methods described herein may be implemented in, as non-limiting examples, hardware, software, firmware, special purpose circuits or logic, general purpose hardware or controller or other computing devices, or some combination thereof.

The foregoing description has provided by way of exemplary and non-limiting examples a full and informative description of the exemplary embodiment of this invention. However, various modifications and adaptations may become apparent to those skilled in the relevant arts in view of the foregoing description, when read in conjunction with the accompanying drawings and the appended claims. However, all such and similar modifications of the teachings of this invention will still fall within the scope of this invention as defined in the appended claims.

1. A method comprising:
receiving input and output samples, wherein said input and output samples are time-aligned;
assigning at least one of said input and output samples to one of a plurality of categories based on said input sample; and estimating at least one characteristic of the amplifier based on the contents of at least one of said plurality of categories.

2. A method according to claim 1, further comprising: determining a phase difference between said input sample and said output sample.

3. The method according to claim 2, wherein said determining a phase difference between said input sample and said output sample further comprises modifying the phase of one of said input and output samples to represent said phase difference.

4. The method according to claim 3, wherein modifying the phase of one of said input and output samples to represent said phase difference further comprises rotating a phase of the output sample backwards by a phase of said input sample.

5. The method of claim 4, wherein rotating the phase of the complex output sample further comprises:
calculating a complex phasor having an opposite phase to said input sample; and
multiplying said output sample with said complex phasor.

6. The method according to claim 1, wherein assigning at least one of said input and output samples to one of a plurality of categories further comprises determining a bin index based on a magnitude of said input sample.

7. The method according to claim 6, wherein assigning at least one of said input and output samples to one of a plurality of categories further comprises storing said output sample in a bin of a first bin array, said bin having an index equal to said determined bin index.

8. The method according to claim 7, wherein assigning at least one of said input and output samples to one of a plurality of categories further comprises storing said magnitude of said input sample in a bin of a second bin array, said bin having an index equal to said determined bin index.

9. The method of claim 7, wherein said storing said output sample in a bin further comprises adding the output sample to the contents of said bin of said first bin array.

10. The method of claim 8, wherein said storing said magnitude of said input sample in a bin further comprises adding the magnitude of said input sample to the contents of said bin of said second bin array.

11. The method according to claim 9, wherein said estimating at least one characteristic of the amplifier further comprises dividing the contents of said bin in said first bin array by the contents of said bin in said second bin array, said bins having a common bin index.

12. The method according to claim 11, wherein said estimating at least one characteristic of the amplifier further comprises estimating a gain error for said amplifier based on the magnitude of a result of said division.

13. The method according to claim 11, wherein said estimating at least one characteristic of the amplifier further comprises estimating a phase error for said amplifier based on a phase of a result of said division.

14. The method according to claim 8, wherein said storing said magnitude of said input sample further comprises applying a first function to the magnitude of said input sample prior to storing.

15. The method according to claim 14, wherein said first function is a square function.

16. The method according to claim 7, wherein said storing said output sample further comprises applying a second function to the output sample prior to storing.

17. The method according to claim 16, wherein said second function comprises multiplying said output sample by the magnitude of the output sample.

18. The method according to claim 14, wherein said estimating at least one characteristic of the amplifier further comprises applying a third function to the contents of each bin in said second bin array.

19. The method according to claim 18, wherein said third function comprises a square root function.

20. The method according to claim 16, wherein said estimating at least one characteristic of the amplifier further comprises applying a fourth function to the contents of each bin in said first bin array.

21. The method according to claim 20, wherein said fourth function is defined by the equation:
y=\sqrt{abs(aᵢ)}*l^{j*arg(a}^{ᵢ}⁾
wherein aᵢ defines the contents of the bin in said first bin array with bin index i, and j is equal to the square root of minus one.

22. An apparatus comprising:
a receiving unit configured to receive time-aligned input and output samples;
an assigning unit configured to assign at least one of said input and output samples to one of a plurality of categories based on said input sample; and
an estimating unit configured to estimate at least one characteristic of the amplifier based on the contents of at least one of said plurality of categories.

23. The apparatus of claim 22 further comprising a phase determining unit configured to determine a phase difference between said input sample and said output sample.

24. The apparatus of claim 23, wherein said phase determining unit is further configured to modify the phase of one of said input and output samples to represent said phase difference.

25. The apparatus of claim 22, wherein said assigning unit is further configured to determine a bin index based on a magnitude of said input sample.

26. The apparatus of claim 25, wherein said assigning unit further comprises:
a first bin array comprising a plurality of bins; and
a storing unit configured to store said output sample in a bin of said first bin array, said bin having an index equal to the determined bin index.

27. The apparatus of claim 26, wherein said assigning unit further comprises a second bin array comprising a plurality of bins; and
wherein said storing unit is further configured to store said magnitude of said input sample in a bin in said second bin array, said bin having an index equal to the determined bin index.

28. The apparatus of claim 26, wherein said storing unit is further configured to store said output sample in said bin in said first bin array by adding the output sample to the contents of the array.

29. The apparatus of claim 26, wherein said storing unit is further configured to store said magnitude of said input sample in said bin in said second bin array by adding the magnitude of said input sample to the contents of the array.

30. The apparatus of claim 29, wherein said estimating unit comprises a divider configured to divide the contents of said bin in said first bin array by the contents of said bin in said second bin array, said bins having a common bin index.

31. An apparatus comprising:
receiving means for receiving time-aligned input and output samples;
assigning means for assigning at least one of said input and output samples to one of a plurality of categories based on said input sample; and
estimating means for estimating at least one characteristic of the amplifier based on the contents of at least one of said plurality of categories.

32. A computer program code means configured to perform the steps of claim 1 when the computer program code means is run on a processor.
